(19) United States
(12) Patent Application Publication
(10) Pub. No.: US 2016/0141755 A1
(43) Pub. Date: May 19, 2016

(54) METHOD AND APPARATUS FOR A COMMUNICATION DEVICE

(71) Applicant: NOKIA TECHNOLOGIES OY, Espoo (FI)

(72) Inventor: Juha HALLIVUORI, Tampere (FI)

(21) Appl. No.: 14/900,608

(22) PCT Filed: Jun. 28, 2013
(86) PCT No.: PCT/FI2013/050719

§ 371 Date: Dec. 21, 2015

(51) Int. Cl. H01Q 5/335; H03H 7/46; H03H 7/01; H01Q 5/35

(52) U.S. Cl. CPC H01Q 5/335; H01Q 5/35; H03H 7/463; H03H 7/01

(57) ABSTRACT

There are disclosed various methods for a communication device and apparatuses comprising an antenna and a transmitter. In some embodiments of the method a transmission signal is provided to a first feed point (126) of an antenna (102) having a first impedance and to a second feed point (128) having a second impedance. In some embodiments the apparatus comprises an antenna (102) having a first feed point (126) and a second feed point (128). The first feed point (126) has a first impedance and the second feed point (128) has a second impedance. The antenna (102) is adapted to combine the transmission signal provided to the first feed point (126) and the transmission signal provided to the second feed point (128) to a combined signal to be radiated by the antenna (102).

### TECHNICAL FIELD

The present invention relates to a method for a communication device and an apparatus comprising an antenna and a transmitter.

### BACKGROUND

This section is intended to provide a background or context to the invention that is recited in the claims. The description herein may include concepts that could be pursued, but are not necessarily ones that have been previously conceived or pursued. Therefore, unless otherwise indicated herein, what is described in this section is not prior art to the description and claims in this application and is not admitted to be prior art by inclusion in this section.

Apparatuses which are able to wirelessly communicate at more than one frequency band may use multiple antennas and/or multiple power amplifiers to feed transmission signals to one or more of the multiple antennas. Therefore, the available space for such constructions may be limited wherein the number of available frequency bands may be quite limited or the size of such communication device may become larger than desired.

Another challenge in some implementations may be due to the impedance of the interface between the power amplifier and the antenna. The impedance may be designed to be about 50Ω which may not be optimal for good enough efficiency in some cases.

### SUMMARY

Various embodiments provide a method and apparatus for coupling a transmitter signal to an antenna so that the same power amplifier circuitry and antenna may be used in multiple frequency bands. In some embodiments a transmission signal is divided into two separate branches wherein one of the branches is fed to a first amplifier, which is coupled to the antenna at a first feed point and the other branch is fed to a second amplifier, which is coupled to the antenna at a second feed point. Impedance of the first feed point is different from the impedance of the second feed point. The interface provided by a lower impedance feed point can be seen as a current-mode interface for the transmission signal and the interface provided by a higher impedance feed point can be seen as a voltage-mode interface for the transmission signal. The low impedance feed point is provided with the transmission signal generated by the transmitter and the high impedance feed point is provided with a phase adjusted transmission signal. In some embodiments the amplitude and/or the phase of one or both of the two transmission signals may also be adjusted before coupling to the antenna. In some embodiments the impedance at the low impedance feed point is lower than 50Ω, for example about 1 to 2Ω, and the impedance at the high impedance feed point is higher than 50Ω, for example about 5 kΩ.

Various aspects of examples of the invention are provided in the detailed description.

According to a first aspect, there is provided a method comprising:
providing a transmission signal to a first feed point of an antenna having a first impedance;
providing the transmission signal to a second feed point of the antenna having a second impedance; and
combining the transmission signal provided to the first feed point and the transmission signal provided to the second feed point in the antenna to a combined signal to be radiated by the antenna.

According to a second aspect, there is provided an apparatus comprising:
an antenna comprising a first feed point and a second feed point, the first feed point having a first impedance and the second feed point having a second impedance;
a first interface to provide a transmission signal to the first feed point; and
a second interface to provide the transmission signal to the second feed point;
wherein the antenna is adapted to combine the transmission signal provided to the first feed point and the transmission signal provided to the second feed point to a combined signal to be radiated by the antenna.

According to a third aspect, there is provided an apparatus comprising:
means for providing a transmission signal to a first feed point of an antenna having a first impedance;
means for providing the transmission signal to a second feed point of the antenna having a second impedance; and
means for combining the transmission signal provided to the first feed point and the transmission signal provided to the second feed point in the antenna to a combined signal to be radiated by the antenna.

In some embodiments the impedance of the first feed point is lower than 50Ω and the impedance at the second impedance feed point is higher than 50Ω.

In some embodiments the first interface is at a low impedance portion of the antenna.

In some embodiments the second interface is at a high impedance portion of the antenna.

In some embodiments the first interface is at a high impedance portion of the antenna; and the second interface is at a low impedance portion of the antenna.

In some embodiments a first amplifier is used for providing the transmission signal to the first feed point; and a second amplifier is used for providing the transmission signal to the second feed point.

In some embodiments the first amplifier is used in a current mode; and the second amplifier is used in a voltage mode.

In some embodiments the antenna is a loop antenna.

In some embodiments the antenna is a patch antenna.

In some embodiments the antenna is a strip antenna.

In some embodiments the antenna comprises a radiator and a ground level.

Transmission efficiency may be improved when providing the transmission signal to at least two different locations of the antenna. Therefore, more transmission power may be achieved without substantially increasing the energy consumption of the transmitter.

### BRIEF DESCRIPTION OF THE DRAWINGS

For a more complete understanding of example embodiments of the present invention, reference is now made to the following descriptions taken in connection with the accompanying drawings in which:

FIG. 1 shows a block diagram of an apparatus according to an example embodiment;

FIG. 2 shows an apparatus according to an example embodiment;

FIG. 3 shows an example of an arrangement for wireless communication comprising a plurality of apparatuses, networks and network elements;

FIG. 4a shows a simplified block diagram of an apparatus according to an example embodiment;

FIG. 4b shows a principle of coupling a transmitter to an antenna;

FIG. 4c shows an example of an arrangement for coupling a transmitter to an antenna;

FIG. 5 shows an example of the coupling of a transmitter to an antenna;

FIG. 6 shows another example of an antenna with at least two feed points;

FIG. 7 shows yet another example of an antenna with at least two feed points;

FIG. 8 shows still another example of an antenna with at least two feed points; and

FIG. 9 depicts a method according to an embodiment.

### DETAILED DESCRIPTION OF SOME EXAMPLE EMBODIMENTS

The following embodiments are exemplary. Although the specification may refer to “an”, “one”, or “some” embodiment(s) in several locations, this does not necessarily mean that each such reference is to the same embodiment(s), or that the feature only applies to a single embodiment. Single features of different embodiments may also be combined to provide other embodiments.

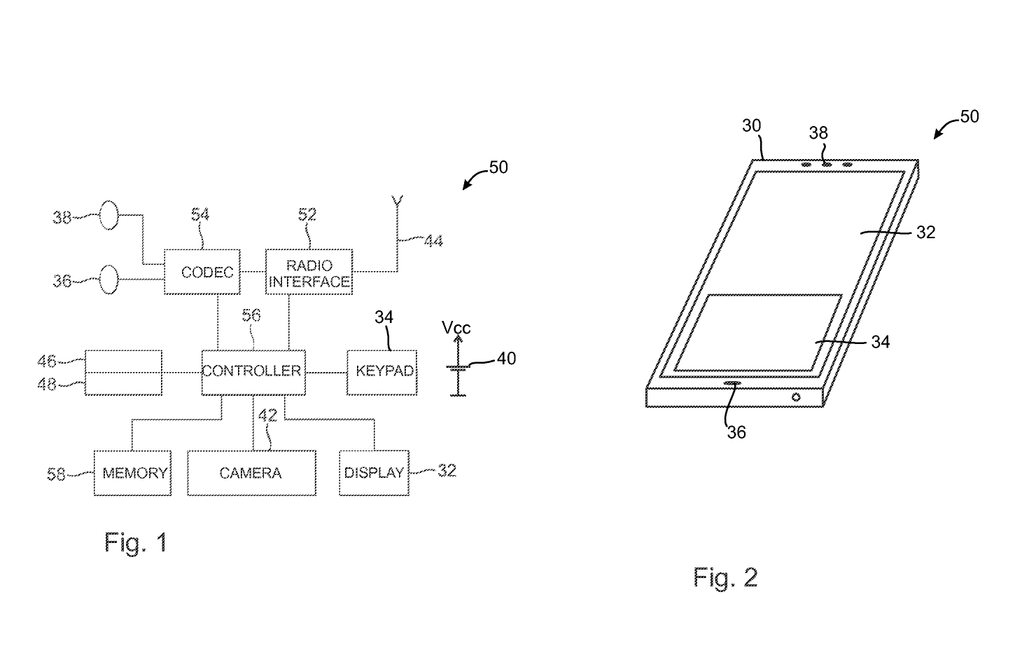

The following describes in further detail suitable apparatus and possible mechanisms for implementing the embodiments of the invention. In this regard reference is first made to FIG. 1 which shows a schematic block diagram of an exemplary apparatus or electronic device 50 depicted in FIG. 2, which may incorporate a receiver front end according to an embodiment of the invention.

The electronic device 50 may for example be a mobile terminal or user equipment of a wireless communication system. However, it would be appreciated that embodiments of the invention may be implemented within any electronic device or apparatus which may require reception of radio frequency signals.

The apparatus 50 may comprise a housing 30 for incorporating and protecting the device. The apparatus 50 further may comprise a display 32 in the form of a liquid crystal display. In other embodiments of the invention the display may be any suitable display technology suitable to display an image or video. The apparatus 50 may further comprise a keypad 34. In other embodiments of the invention any suitable data or user interface mechanism may be employed. For example the user interface may be implemented as a virtual keyboard or data entry system as part of a touch-sensitive display. The apparatus may comprise a microphone 36 or any suitable audio input which may be a digital or analogue signal input. The apparatus 50 may further comprise an audio output device which in embodiments of the invention may be any one of: an earpiece 38, speaker, or an analogue audio or digital audio output connection. The apparatus 50 may also comprise a battery 40 (or in other embodiments of the invention the device may be powered by any suitable mobile energy device such as solar cell, fuel cell or clockwork generator). The apparatus may further comprise an infrared port 42 for short range line of sight communication to other devices. In other embodiments the apparatus 50 may further comprise any suitable short range communication solution such as for example a Bluetooth wireless connection or a USB/firewire wired connection.

The apparatus 50 may comprise a controller 56 or processor for controlling the apparatus 50. The controller 56 may be connected to memory 58 which in embodiments of the invention may store both data and/or may also store instructions for implementation on the controller 56. The controller 56 may further be connected to codec circuitry 54 suitable for carrying out coding and decoding of audio and/or video data or assisting in coding and decoding carried out by the controller 56.

The apparatus 50 may further comprise a card reader 48 and a smart card 46, for example a UICC and UICC reader for providing user information and being suitable for providing authentication information for authentication and authorization of the user at a network.

The apparatus 50 may comprise radio interface circuitry 52 connected to the controller and suitable for generating wireless communication signals for example for communication with a cellular communications network, a wireless communications system or a wireless local area network. The apparatus 50 may further comprise an antenna 102 connected to the radio interface circuitry 52 for transmitting radio frequency signals generated at the radio interface circuitry 52 to other apparatus(es) and for receiving radio frequency signals from other apparatus(es).

In some embodiments of the invention, the apparatus 50 comprises a camera capable of recording or detecting imaging.

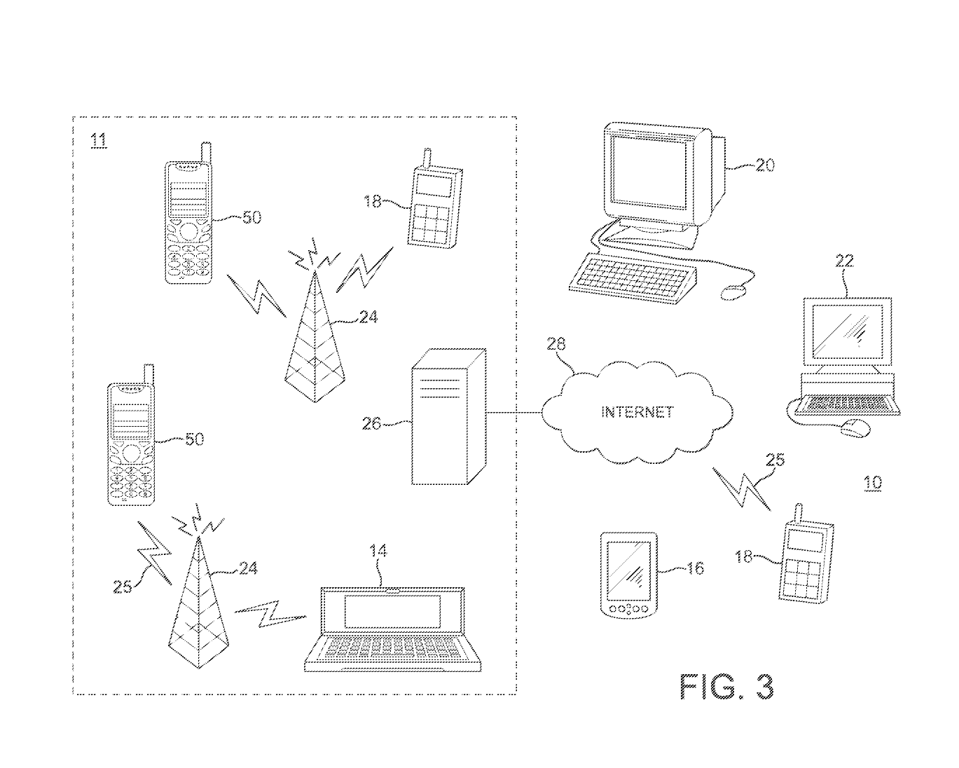

With respect to FIG. 3, an example of a system within which embodiments of the present invention can be utilized is shown. The system 10 comprises multiple communication devices which can communicate through one or more networks. The system 10 may comprise any combination of wired and/or wireless networks including, but not limited to a wireless cellular telephone network (such as a GSM, UMTS, CDMA network etc.), a wireless local area network (WLAN) such as defined by any of the IEEE 802.x standards, a Bluetooth personal area network, an Ethernet local area network, a token ring local area network, a wide area network, and the Internet.

For example, the system shown in FIG. 3 shows a mobile telephone network 11 and a representation of the internet 28. Connectivity to the internet 28 may include, but is not limited to, long range wireless connections, short range wireless connections, and various wired connections including, but not limited to, telephone lines, cable lines, power lines, and similar communication pathways.

The example communication devices shown in the system 10 may include, but are not limited to, an electronic device or apparatus 50, a combination of a personal digital assistant (PDA) and a mobile telephone 14, a PDA 16, an integrated messaging device (IMD) 18, a desktop computer 20, a notebook computer 22. The apparatus 50 may be stationary or mobile when carried by an individual who is moving. The apparatus 50 may also be located in a mode of transport including, but not limited to, a car, a truck, a taxi, a bus, a train, a boat, an airplane, a bicycle, a motorcycle or any similar suitable mode of transport.

Some or further apparatus may send and receive calls and messages and communicate with service providers through a wireless connection 25 to a base station 24. The base station 24 may be connected to a network server 26 that allows communication between the mobile telephone network 11 and the internet 28. The system may include additional communication devices and communication devices of various types.

The communication devices may communicate using various transmission technologies including, but not limited to, code division multiple access (CDMA), global systems for mobile communications (GSM), universal mobile telecommunications system (UMTS), time divisional multiple access (TDMA), frequency division multiple access (FDMA), transmission control protocol-internet protocol (TCP-IP), short messaging service (SMS), multimedia messaging service (MMS), email, instant messaging service (IMS), Bluetooth, IEEE 802.11 and any similar wireless communication technology. A communications device involved in implementing various embodiments of the present invention may communicate using various media including, but not limited to, radio, infrared, laser, cable connections, and any suitable connection. In the following some example implementations of apparatuses utilizing the micromechanical resonator will be described in more detail.

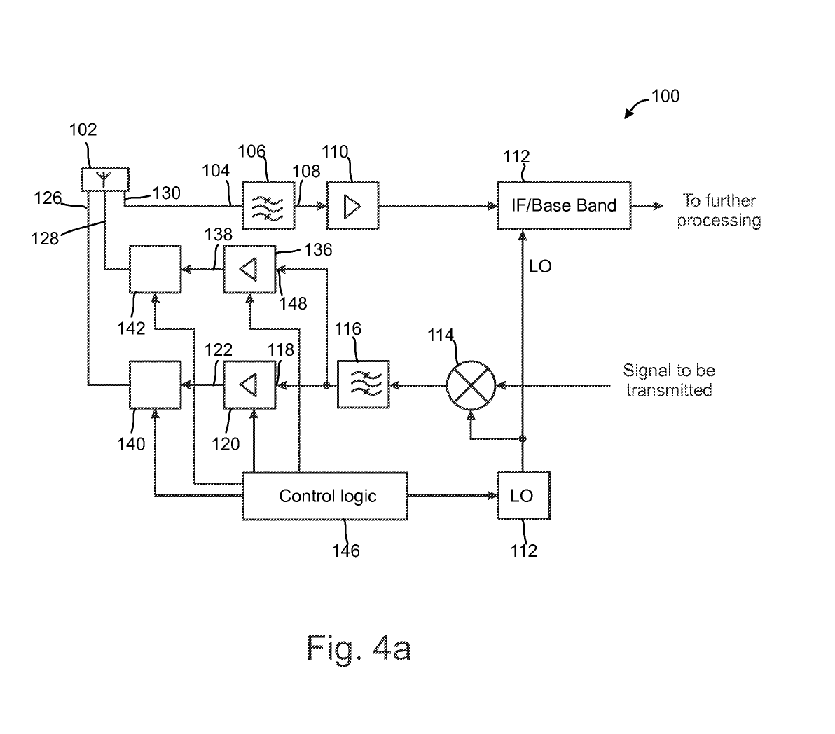

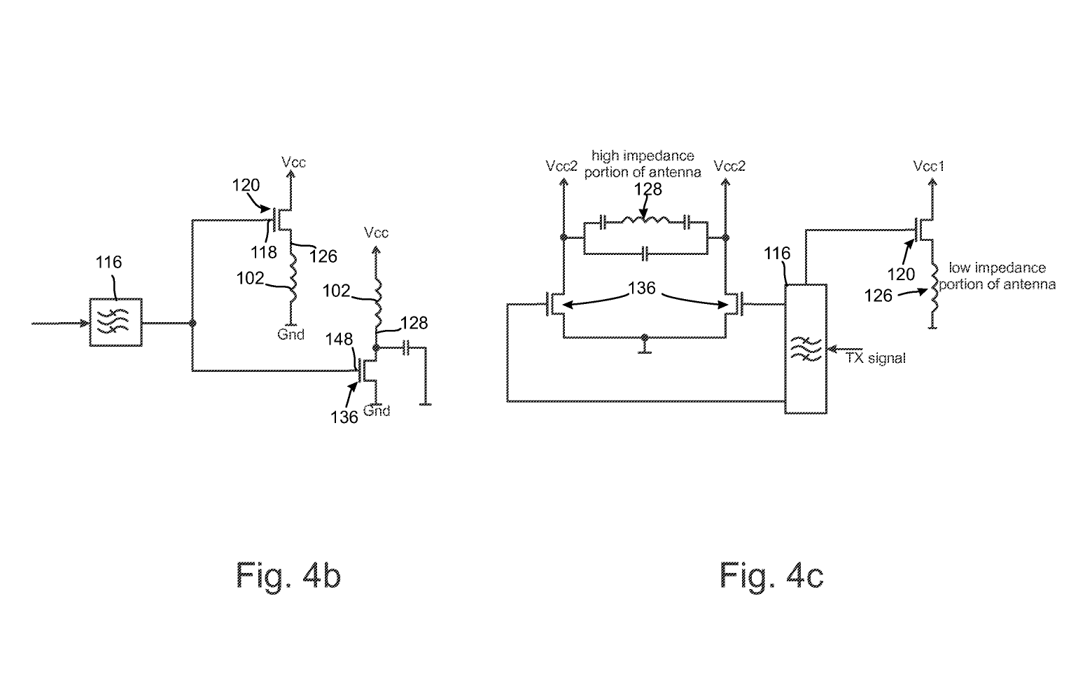

FIG. 4a shows a block diagram of radio frequency (RF) elements of an apparatus 100 according to an example embodiment. In this non-limiting example embodiment the apparatus 100 comprises a transmitter and a receiver. This kind of apparatus may also be called as a transceiver.

The receiver converts a received radio signal first to the intermediate frequency and then to a baseband. In some other embodiments the intermediate frequency part is not needed wherein such receivers, which may also be called as direct-conversion receivers, convert a received radio signal directly to the baseband.

In the example embodiment of FIG. 4a, the apparatus comprises an antenna 102 for receiving and transmitting radio frequency (RF) signals. In some embodiments there may be separate antennas for the receiver and the transmitter.

The apparatus may be able to transmit and receive at the same time. For example, the apparatus may be operating by duplexing between the TX and RX frequencies in an FDD (Frequency Division Duplex) mode.

In this example embodiment the antenna 102 is connected to an input 104 of a first bandpass filter 106 for filtering received RF signals to eliminate or attenuate signals which are outside the desired frequency range of the RF signals. The filtered signals may be output 110 to a first amplifier 108 for amplifying the signals. The first amplifier 108 may be a low-noise amplifier (LNA) or another kind of amplifier suitable for amplifying RF signals. The amplified RF signals may be converted to intermediate signals (IF) or directly to base band signals by mixing the RF signals with one or more local oscillator signals LO from the same local oscillator 112 or from another local oscillator. The structure of the IF/base band elements 110 of the receiver are not depicted in more detail in this context.

In some embodiments the apparatus 100 may be designed to operate in more than one communication system wherein the frequency bands used by the communication systems may vary. For example, the frequency bands which the apparatus 100 should be able to utilize may be located near 700 MHz, near 900 MHz, near 1800 MHz, and near 2500 MHz, or even at higher frequencies, e.g. up to about 5 GHz.

In some embodiments the received signals may be converted to digital representations by an analogue-to-digital conversion before converting the signals to base band signals. For example, the analogue-to-digital conversion may be performed in the front end wherein the filtered analogue radio frequency signals may be converted to digital representations (e.g. samples), wherein the other stages of the receiver may operate using the digital representations of the received signals.

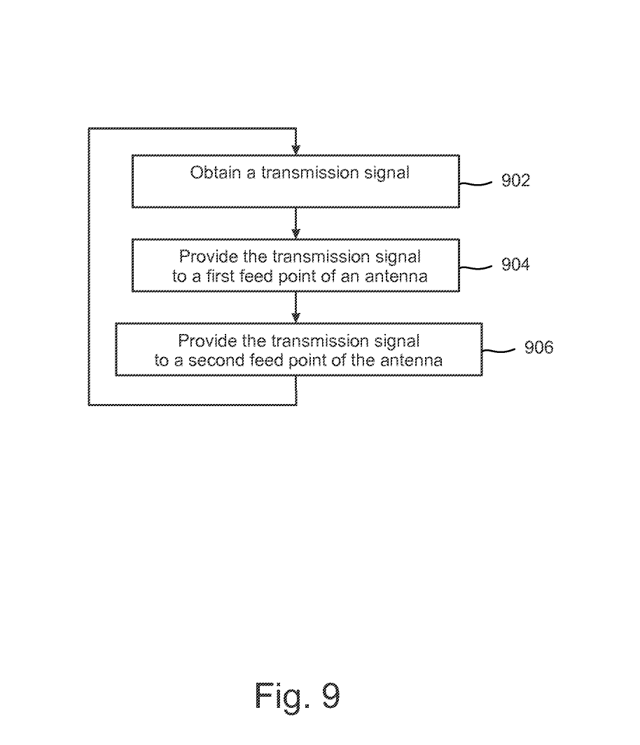

FIG. 4a also depicts a part of a transmitter of the apparatus and FIG. 8 depicts a method according to an embodiment. A signal to be transmitted is input to the mixer 114 of the transmitter in which the signal is mixed with the local oscillator signal from the local oscillator 112. The mixing result is band bass filtered by a second band bass filter 116 so that the signals at the correct transmitting frequency (block 902 in FIG. 9) may be connected to a first amplifier 120 to be amplified and coupled (block 904) to a first feed point 126 of the antenna 102 and to a second amplifier 136 to be amplified and coupled (block 906) to a second feed point 128 of the antenna 10 having a different impedance than the first feed point 126.

In some embodiments the output 122 of the first amplifier 120 may not be directly connected to the first feed point 126 of the antenna 102 but to a first tuning element 140 which may be used to tune e.g. the resonance of the antenna 102 at the first feed point 126. Correspondingly, the output 138 of the second amplifier 136 may not be directly connected to the second feed point 128 of the antenna 102 but to a second tuning element 142 which may be used to tune e.g. the resonance of the antenna 102 at the second feed point 128. The first tuning element 140 and/or the second tuning element 142 may be tuned e.g. by the control logic 146. The control logic 146 may, for example, adjust a capacitance value of an adjustable capacitor to obtain a correct resonance for the feed point 126, 128.

Tuning of the resonances of the feed points 126, 128 may be performed e.g. when the apparatus changes to operate from one frequency band to another frequency band. In some embodiments the tuning may also be performed when the apparatus changes to operate in another communication channel within the same frequency band, if the frequencies of the communication channels are not close to each other.

FIG. 4b shows the principle of the usage of multiple feed points in transmission of RF signals according to some embodiments. The input 118 of the first amplifier 120 is provided with the signal to be transmitted for amplification and/or for impedance matching. The first amplifier 120 may comprise e.g. a MOSFET transistor (Metal Oxide on Silicon Field Effect Transistor) or some other appropriate element suitable for providing amplification to the input signal. The input 118 of the first amplifier may be the gate of the MOSFET transistor. In this embodiment the first amplifier 120 is feeding the lower impedance feed point 126 of the antenna. Hence, the first amplifier 120 is set to operate in a current mode wherein the amplified transmission signal is coupled either directly or via the tuning element 140 (not shown in FIG. 4b) to the first feed point 126 of the antenna. Due to the current mode the operating voltage of the first amplifier 120 may be set quite low. In some embodiments the voltage at the drain of the MOSFET transistor may be below 3 V, even as low as about 1 V. It should be mentioned, however, that these values are just non-limiting examples and in practical implementations also other voltage values may be used, even lower than 1 V or higher than 3 V.

The second amplifier 136 may also comprise e.g. a MOSFET transistor or some other appropriate element suitable for providing amplification to the input signal. The input 148 of the second amplifier 136 may be the gate of the MOSFET transistor. In this embodiment the second amplifier 136 is feeding the higher impedance feed point 128 of the antenna. Hence, the second amplifier 136 is set to operate in a voltage mode wherein the amplified transmission signal is coupled either directly or via the tuning element 142 (not shown in FIG. 4b) to the second feed point 128 of the antenna. Due to the voltage mode the current through the second amplifier 136 may be set quite low but the operating voltage may be set rather high, possibly much higher than the operating voltage of the first amplifier. In some embodiments the voltage at the drain of the MOSFET transistor may be above the operating voltage of the communication device. This may be achieved by using appropriate DC-DC converters such as charge pumps. In some embodiments the voltage at the drain of the MOSFET transistor may be above 3 V. It should be mentioned, however, that these values are just non-limiting examples and in practical implementations also other voltage values may be used.

FIG. 4b is only a simplified illustration of the principle of the feeding of the antenna 102. In practical implementations some further circuitry may be needed e.g. to provide proper DC voltage levels in the amplifiers 120, 136. Coupling of the amplifiers 120, 136 to the feed points 126, 128 of the antenna 102 may need some further arrangements. For example, the second feed point 128 may be implemented with a capacitive interface with the radiator of the antenna 102, wherein the output 138 of the second amplifier 136 is connected to the second feed point 128 without galvanic connection to the radiator.

FIG. 4c shows an example of an arrangement for coupling a transmitter to an antenna. The transmission signal is filtered by the band-pass filter 116, which may be, for example, a so called balun filter. The filtered transmission signal is coupled to the first amplifier 120, which in this example comprises one transistor. The output of the first amplifier 120 is coupled to the first feed point 126. The filtered signal is also coupled to the second amplifier 136 comprising a pair of transistors, which amplify the signal and feed the amplified signal to the second feed point 128, which in this example is a capacitive interface to the antenna.

In some embodiments the transmission signal at the input 148 of the second amplifier 136 may be phase shifted transmission signal with respect to the transmission signal at the input 118 of the first amplifier 120.

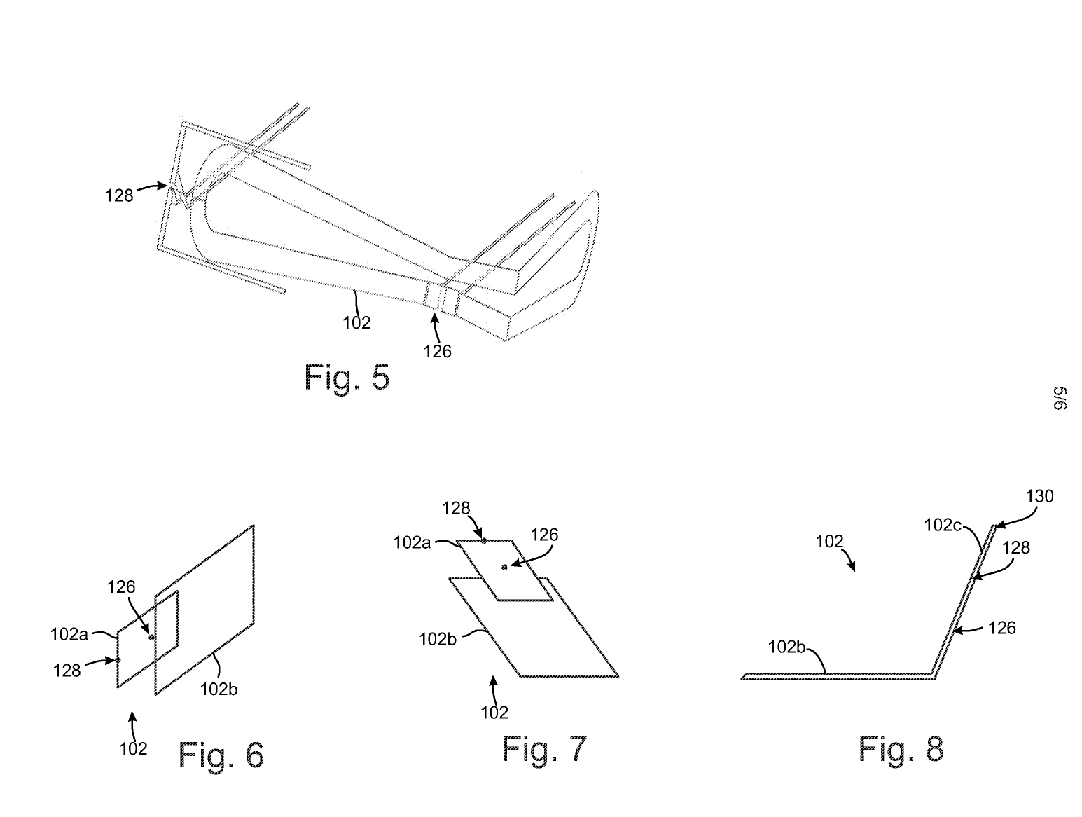

In FIG. 5a an example embodiment of the antenna 102 is depicted. The antenna 102 is formed to a loop comprising one or more turns and may also be formed as a strip of conducting metal such as a copper strip in a loop form. The first feed point 126 may be formed as a differential feed point wherein the transmission signal is fed to the feed point as a differential signal. In this embodiment the coupling of the transmission signal is capacitive, series impedance coupling. The resonance of the first feed point 126 may be adjusted by using e.g. a tunable capacitance (not shown) in parallel or in series with the first feed point 126. The second feed point 128 may also be formed as a differential feed point wherein the transmission signal is fed to the feed point as a differential signal. In this embodiment the coupling of the transmission signal is capacitive, parallel impedance coupling. The coupling is implemented with two stripes located near the high impedance location of the antenna. In this example the high impedance location is at the end of the loop, which can be seen from FIG. 5a. There may also be another high impedance location in the antenna 102 at the other end of the loop. The resonance of the second feed point 128 may also be adjusted by using e.g. a tunable capacitance (not shown) in parallel or in series with the second feed point 128.

In some embodiments it may not be necessary to adjust the impedances of the feed points when the transmitter and the receiver are operating within the same frequency band, but the adjustment of the impedances may be necessary when changing the operation of the transmitter and the receiver to another frequency band.

In some embodiments transmission signals may be frequency selective transmission signals.

When using the antenna structure similar to the antenna 102 of FIG. 5 it may be possible to use the other high impedance location as a feed point for the receiver, or the second feed point 128 may be used as the feed point for the receiver.

In some embodiments the impedance at the first feed point 126 is lower than 50Ω, for example about 1 to 2Ω, and the impedance at the second feed point 128 is higher than 50Ω, for example hundreds or thousands ohms, e.g. about 5 kΩ.

In other words, some embodiments utilize two or more different impedance locations of the antenna. Embodiments of the present invention provide intrinsic isolation without transmission lines or bulky duplexers. The structures are tunable and suitable for variety of different bands and systems. Good isolation between ports may be achieved even if the ports are matched and used at the same frequency at the same antenna when one of the ports has high impedance and the other port has low impedance. The ports can be used independently from each other at many different frequencies. The first amplifier 120 and the second amplifier 136 can be regarded as a power amplifier of the transmitter of the communication device. The same amplifier circuitry can be used in more than one frequency band. Therefore, separate power amplifiers for different frequency bands may not be needed but the combined amplifier may cover very large frequency range. Also the size required by the power amplifier is less compared to the situation in which more than one power amplifier is used. The local oscillator frequency may be used to set the correct transmission frequency.

In the following some additional example structures of the antenna 102 and the feed points 126, 128 are depicted in a simplified manner with reference to FIGS. 6 and 7. The antennas 102 of FIGS. 6 and 7 are so called patch antennas which comprise a radiator 102a and a ground plane 102b. The shape of both the radiator 102a and the ground plane 102b is, for example, rectangular. The first feed point 126 may be formed as a single-ended feed point wherein the transmission signal is fed to the feed point as a single-ended signal. The radiator 102a and the ground plane 102b are installed such that they are substantially parallel to each other and there is a distance between them. The distance, size and the aspect ratio of the rectangular plates may be selected to obtain desired operational parameters for the antenna 102, such as the frequency range in which the antenna 102 may provide good efficiency.

In these example antennas 102 the first feed point 126 is located substantially at the centre of the radiator 102a and the second feed point 128 is located in the middle of an edge of the radiator 102a.

The radiator 102a and the ground plane 102b may be formed by using a sheet of conducting metal such as copper, aluminium or other suitable material. In some embodiments the radiator 102a and the ground plane 102b may be formed on a printed circuit board e.g. in such a way that the radiator is formed on one side of the printed circuit board and the ground plane is formed using the opposite side of the printed circuit board or another layer inside the printed circuit board, if a multi-layer printed circuit board is used. The radiator and the ground plane may be formed by etching, printing and/or other techniques suitable for this purpose.

FIG. 8 illustrates an example of a strip-like antenna in which the radiator 102b comprises a strip having a certain length. The antenna 102 may be provided with a feed line 102c to be used for feeding transmission signals to the antenna. The feed line 102c may comprise feed points 126, 128, 130 at which the transmission signals may be coupled to the antenna and which provide different impedances for the coupling. For example, the first feed point 126 may provide the lowest impedance of the three feed points 126, 128, 130, the second feed point 128 may provide a moderate impedance higher than the impedance at the first feed point, and the third feed point 130 may provide the highest impedance of the three feed points 126, 128, 130. The exact location of the different feed points 126, 128, 130 may vary in different embodiments.

In the embodiments in which the same antenna 102 is used both for the transmitter and the receiver, the receiver may be coupled to the antenna 102 e.g. at the second feed point or at a separate feed point such as a third feed point 130 illustrated in FIG. 4a and in FIG. 8.

Although the above examples describe embodiments of the invention operating within a wireless communication device, it would be appreciated that the invention as described above may be implemented as a part of any apparatus comprising a circuitry in which radio frequency signals are transmitted and received. Thus, for example, embodiments of the invention may be implemented in a mobile phone, in a base station, in a computer such as a desktop computer or a tablet computer comprising radio frequency communication means (e.g. wireless local area network, cellular radio, etc.).

In general, the various embodiments of the invention may be implemented in hardware or special purpose circuits or any combination thereof. While various aspects of the invention may be illustrated and described as block diagrams or using some other pictorial representation, it is well understood that these blocks, apparatus, systems, techniques or methods described herein may be implemented in, as non-limiting examples, hardware, software, firmware, special purpose circuits or logic, general purpose hardware or controller or other computing devices, or some combination thereof.

Embodiments of the inventions may be practiced in various components such as integrated circuit modules. The design of integrated circuits is by and large a highly automated process. Complex and powerful software tools are available for converting a logic level design into a semiconductor circuit design ready to be etched and formed on a semiconductor substrate.

Programs, such as those provided by Synopsys, Inc. of Mountain View, Calif. and Cadence Design, of San Jose, Calif. automatically route conductors and locate components on a semiconductor chip using well established rules of design as well as libraries of pre stored design modules. Once the design for a semiconductor circuit has been completed, the resultant design, in a standardized electronic format (e.g., Opus, GDSII, or the like) may be transmitted to a semiconductor fabrication facility or “fab” for fabrication.

The foregoing description has provided by way of exemplary and non-limiting examples a full and informative description of the exemplary embodiment of this invention. However, various modifications and adaptations may become apparent to those skilled in the relevant arts in view of the foregoing description, when read in conjunction with the accompanying drawings and the appended claims. However, all such and similar modifications of the teachings of this invention will still fall within the scope of this invention.

In the following some examples will be provided.

According to a first example, there is provided a method comprising:
providing a transmission signal to a first feed point of an antenna having a first impedance;
providing the transmission signal to a second feed point of the antenna having a second impedance; and
combining the transmission signal provided to the first feed point and the transmission signal provided to the second feed point in the antenna to a combined signal to be radiated by the antenna.

In some embodiments the method comprises:
providing the transmission signal to a low impedance portion of the antenna by the first feed point.

In some embodiments the method comprises:
providing the transmission signal to a high impedance portion of the antenna by the second feed point.

In some embodiments the method comprises:
providing an impedance lower than 50Ω at the first feed point; and
providing an impedance higher than 50Ω at the second feed point.

In some embodiments the method comprises:
providing the first feed point at a low impedance portion of the antenna; and
providing the second feed point at a high impedance portion of the antenna.

In some embodiments the method comprises:
using a first amplifier for providing the transmission signal to the first feed point; and
using a second amplifier for providing the transmission signal to the second feed point.

In some embodiments the method comprises:
using the first amplifier in a current mode; and
using the second amplifier in a voltage mode.

In some embodiments the method comprises using a loop antenna as the antenna.

In some embodiments the method comprises using a patch antenna as the antenna.

In some embodiments the method comprises using a strip antenna as the antenna.

In some embodiments the method comprises using an antenna comprising a radiator and a ground level.

In some embodiments the method comprises adjusting at least one of the following before providing the transmission signal to the second feed point:
the amplitude of the transmission signal;
the phase of the transmission signal.

In some embodiments the method comprises:
providing a third feed point at the antenna for receiving signals from the antenna.

According to a second example there is provided an apparatus comprising:
an antenna comprising a first feed point and a second feed point, the first feed point having a first impedance and the second feed point having a second impedance;
a first interface to provide a transmission signal to the first feed point; and
a second interface to provide the transmission signal to the second feed point;
wherein the antenna is adapted to combine the transmission signal provided to the first feed point and the transmission signal provided to the second feed point to a combined signal to be radiated by the antenna.

In some embodiments the first feed point is at a low impedance portion of the antenna.

In some embodiments the second feed point is at a high impedance portion of the antenna.

In some embodiments of the apparatus the first impedance is lower than 50Ω; and the second impedance is higher than 50Ω.

In some embodiments of the apparatus the first feed point has a first impedance; and the second feed point has a second impedance lower than the first impedance.

In some embodiments the apparatus further comprises:
a first amplifier for providing the transmission signal to the first feed point; and
a second amplifier for providing the transmission signal to the second feed point.

In some embodiments the apparatus further comprises:
the first amplifier is adapted to be used in a current mode; and
the second amplifier is adapted to be used in a voltage mode.

In some embodiments of the apparatus the antenna is one of the following:
a loop antenna;
a patch antenna;
a strip antenna.

In some embodiments the antenna comprises a radiator and a ground plane.

In some embodiments of the apparatus the first feed point has a first impedance; and the second feed point has a second impedance higher than the first impedance.

In some embodiments the apparatus further comprises an amplifier for adjusting the amplitude of the transmission signal before providing the transmission signal to the second feed point.

In some embodiments the apparatus further comprises a phase shifter for adjusting the phase of the transmission signal before providing the transmission signal to the second feed point.

In some embodiments of the apparatus the antenna comprises a third feed point adapted to be connected to a receiver for receiving signals from the antenna.

In some embodiments the apparatus is a part of a mobile communication device.

According to a third example, there is provided an apparatus comprising:
means for providing a transmission signal to a first feed point of an antenna having a first impedance;
means for providing the phase shifted transmission signal to a second feed point of the antenna having a second impedance; and
means for combining the transmission signal provided to the first feed point and the transmission signal provided to the second feed point in the antenna to a combined signal to be radiated by the antenna.

In some embodiments the apparatus comprises:
means for providing the transmission signal to a low impedance portion of the antenna by the first feed point.

In some embodiments the apparatus comprises:
means for providing the transmission signal to a high impedance portion of the antenna by the second feed point.

In some embodiments the apparatus comprises:
means for providing an impedance lower than 50Ω at the first feed point; and
means for providing an impedance higher than 50Ω at the second feed point.

In some embodiments the apparatus comprises:
means for providing the first feed point at a low impedance portion of the antenna; and
means for providing the second feed point at a high impedance portion of the antenna.

In some embodiments the apparatus comprises:
means for using a first amplifier for providing the transmission signal to the first feed point; and
means for using a second amplifier for providing the transmission signal to the second feed point.

In some embodiments the apparatus comprises:
means for using the first amplifier in a current mode; and
means for using the second amplifier in a voltage mode.

In some embodiments the apparatus comprises a loop antenna.

In some embodiments the apparatus comprises a patch antenna.

In some embodiments the apparatus comprises a strip antenna.

In some embodiments of the apparatus the antenna comprises a radiator and a ground level.

In some embodiments the apparatus further comprises means for adjusting the amplitude of the transmission signal before providing the transmission signal to the second feed point.

In some embodiments the apparatus further comprises means for adjusting the phase of the transmission signal before providing the transmission signal to the second feed point.

In some embodiments the apparatus comprises:
means for providing a third feed point at the antenna for receiving signals from the antenna.

1-37. (canceled)

38. A method comprising:
providing a transmission signal to a first feed point of an antenna having a first impedance;
providing the transmission signal to a second feed point of the antenna having a second impedance; and
combining the transmission signal provided to the first feed point and the transmission signal provided to the second feed point in the antenna to a combined signal to be radiated by the antenna.

39. The method according to claim 38 comprising:
providing the transmission signal to a low impedance portion of the antenna by the first feed point; and
providing the phase shifted transmission signal to a high impedance portion of the antenna by the second feed point.

40. The method according to claim 38 further comprising:
providing an impedance lower than 50Ω at the first feed point; and
providing an impedance higher than 50Ω at the second feed point.

41. The method according to claim 38 comprising:
providing the first feed point at a low impedance portion of the antenna; and
providing the second feed point at a high impedance portion of the antenna.

42. The method according to claim 38 comprising:
using a first amplifier for providing the transmission signal to the first feed point; and
using a second amplifier for providing the transmission signal to the second feed point.

43. The method according to claim 42 comprising:
using the first amplifier in a current mode; and
using the second amplifier in a voltage mode.

44. The method according to claim 38, wherein the antenna is one of:
a loop antenna;
a patch antenna; or
a strip antenna.

45. The method according to claim, 38 further comprising
adjusting at least one of the following before providing the transmission signal to the second feed point:
the amplitude of the transmission signal;
the phase of the transmission signal.

46. The method according to claim 38 further comprising:
providing a third feed point at the antenna for receiving signals from the antenna.

47. An apparatus comprising:
an antenna comprising a first feed point and a second feed point, the first feed point having a first impedance and the second feed point having a second impedance;
a first interface to provide a transmission signal to the first feed point; and
a second interface to provide the transmission signal to the second feed point;
wherein the antenna is adapted to combine the transmission signal provided to the first feed point and the transmission signal provided to the second feed point to a combined signal to be radiated by the antenna.

48. The apparatus according to claim 47, wherein:
the first feed point is at a low impedance portion of the antenna; and
the second feed point is at a high impedance portion of the antenna.

49. The apparatus according to claim 47, wherein:
the first impedance is lower than 50Ω; and
the second impedance is higher than 50Ω.

50. The apparatus according to claim 47, wherein the first feed point has a first impedance; and the second feed point has a second impedance lower than the first impedance.

51. The apparatus according to claim 47 further comprising:
a first amplifier for providing the transmission signal to the first feed point; and
a second amplifier for providing the transmission signal to the second feed point.

52. The apparatus according to claim 51, wherein:
the first amplifier is adapted to be used in a current mode; and
the second amplifier is adapted to be used in a voltage mode.

53. The apparatus according to claim 47, wherein the antenna is one of the following:
a loop antenna;
a patch antenna;
a strip antenna.

54. The apparatus according to the claim 47, wherein the antenna comprises a radiator and a ground plane.

55. The apparatus according to the claim 47, further comprising an amplifier for adjusting the amplitude of the transmission signal before providing the transmission signal to the second feed point.

56. The apparatus according to the claim 47, further comprising a phase shifter for adjusting the phase of the transmission signal before providing the transmission signal to the second feed point.

57. The apparatus according to the claim 47, wherein the antenna comprises a third feed point adapted to be connected to a receiver for receiving signals from the antenna.
